(19) United States
(12) Patent Application Publication
(10) Pub. No.: US 2024/0431143 A1
(43) Pub. Date: Dec. 26, 2024

(54) ARRAY SUBSTRATE AND DISPLAY APPARATUS

(71) Applicant: BOE Technology Group Co., Ltd., Beijing (CN)

(72) Inventors: Xiaohu Li, Beijing (CN); Lu Wang, Beijing (CN); Zhiqiang Jiao, Beijing (CN); Liangliang Kang, Beijing (CN); Xiaoyun Liu, Beijing (CN); Peng Wang, Beijing (CN)

(73) Assignee: BOE Technology Group Co., Ltd., Beijing (CN)

(21) Appl. No.: 17/907,489

(22) PCT Filed: Dec. 24, 2021
(86) PCT No.: PCT/CN2021/141278

§ 371 Date: Sep. 27, 2022

(51) Int. Cl. H10K 59/122; H10K 59/131; H10K 59/80

(52) U.S. Cl. CPC H10K 59/122; H10K 59/131; H10K 59/80518

(57) ABSTRACT

An array substrate is provided. The array substrate includes a plurality of subpixels. A respective subpixel of the plurality of subpixels includes a first transistor. The first transistor includes a gate electrode; a first electrode on the gate electrode; a semiconductor material layer on a side of the first electrode away from the gate electrode; a second electrode on a side of the semiconductor material layer away from the first electrode; an organic layer on a side of the second electrode away from the semiconductor material layer; and a third electrode on a side of the organic layer away from the second electrode. An orthographic projection of the second electrode on a base substrate at least partially overlaps with an orthographic projection of the organic layer on the base substrate.

### TECHNICAL FIELD

The present invention relates to display technology, more particularly, to an array substrate and a display apparatus.

### BACKGROUND

Display technologies continue to evolve to achieve higher resolutions, higher aperture ratios, and higher display quality. Related display panels such as organic light emitting diode display panels have highly complicated layouts. Vertical organic light emitting transistor display panels have relatively simple layouts, and have found various applications in the display field, particularly in high-resolution display.

### SUMMARY

In one aspect, the present disclosure provides an array substrate, comprising a plurality of subpixels, wherein a respective subpixel of the plurality of subpixels comprises a first transistor; wherein the first transistor comprises a gate electrode; a first electrode on the gate electrode; a semiconductor material layer on a side of the first electrode away from the gate electrode; a second electrode on a side of the semiconductor material layer away from the first electrode; an organic layer on a side of the second electrode away from the semiconductor material layer; and a third electrode on a side of the organic layer away from the second electrode; wherein an orthographic projection of the second electrode on a base substrate at least partially overlaps with an orthographic projection of the organic layer on the base substrate.

Optionally, the orthographic projection of the second electrode on the base substrate at least partially overlaps with an orthographic projection of the semiconductor material layer on the base substrate, and at least partially overlaps with an orthographic projection of the first electrode on the base substrate.

Optionally, an orthographic projection of the gate electrode on the base substrate at least partially overlaps with an orthographic projection of the semiconductor material layer on the base substrate.

Optionally, the second electrode is a reflective electrode.

Optionally, the array substrate further comprises a capping layer on a side of the third electrode away from the second electrode, and configured to extract light reflected by the second electrode.

Optionally, the array substrate further comprises an encapsulating layer on a side of the third electrode away from the second electrode, encapsulating the first transistor.

Optionally, the first transistor is a top-emitting type light emitting transistor; the array substrate is a top-emitting type array substrate; and light emitted from the organic layer emits out of the first transistor along a direction from the second electrode to the third electrode.

Optionally, the first transistor is a bottom-emitting type light emitting transistor; the array substrate is a bottom-emitting type array substrate; and light emitted from the organic layer emits out of the first transistor along a direction from the third electrode to the second electrode.

Optionally, the respective subpixel further comprises a second transistor coupled to the second electrode; the second transistor is configured to connect or disconnect the second electrode with a voltage signal line; and the voltage signal line is a signal line configured to provide a signal to the third electrode.

Optionally, the second electrode is electrically connected to the semiconductor material layer and the organic layer, and is electrically isolated from a pixel definition layer.

Optionally, the second electrode is a substantially transparent electrode.

Optionally, the first electrode is a perforated electrode, configured to allow an electric field produced by the gate electrode to modulate the semiconductor material layer, which functions as at least a part of an active layer of the first transistor.

Optionally, the first electrode comprises a carbon nanotube material.

Optionally, the first electrode comprises a patterned electrode having a plurality of openings.

Optionally, the array substrate further comprises a repellent protective layer defining a plurality of first apertures, a respective first aperture of the plurality of first apertures receiving the second electrode of the respective subpixel.

Optionally, a thickness of the repellent protective layer is 10% to 80% of a thickness of the second electrode.

Optionally, the repellent protective layer comprises an organic topological insulating material.

Optionally, the array substrate further comprises a pixel definition layer defining a plurality of second apertures, a respective second aperture of the plurality of second apertures receiving the semiconductor material layer of the respective subpixel, and receiving at least a part of the second electrode of the respective subpixel.

Optionally, the respective subpixel further comprises a third transistor configured to connect or disconnect the gate electrode with a control signal line.

In another aspect, the present disclosure provides a display apparatus, comprising the array substrate described herein.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2 is a cross-sectional view of a stacked structure in a respective subpixel in some embodiments according to the present disclosure.

FIG. 3 is a circuit diagram of a respective subpixel in some embodiments according to the present disclosure.

FIG. 4A illustrates the structure in plan view of at least a portion of a stacked structure in a respective subpixel in some embodiments according to the present disclosure.

FIG. 4B illustrates the structure of a gate electrode in a respective subpixel of FIG. 4A.

FIG. 4C illustrates the structure of a first electrode in a respective subpixel of FIG. 4A.

FIG. 4D illustrates the structure of a semiconductor material layer in a respective subpixel of FIG. 4A.

FIG. 4E illustrates the structure of a second electrode in a respective subpixel of FIG. 4A.

FIG. 4F illustrates the structure of an organic layer in a respective subpixel of FIG. 4A.

FIG. 4G illustrates the structure of a third electrode in a respective subpixel of FIG. 4A.

FIG. 5 is a cross-sectional view of a respective subpixel in some embodiments according to the present disclosure.

FIG. 6 is a circuit diagram of a respective subpixel in some embodiments according to the present disclosure.

FIG. 7 is a cross-sectional view of a stacked structure in a respective subpixel in some embodiments according to the present disclosure.

FIG. 8 is a cross-sectional view of a respective subpixel in some embodiments according to the present disclosure.

FIG. 9 illustrates the structure of a respective first aperture in some embodiments according to the present disclosure.

FIG. 10 illustrates the structure of a perforated electrode in some embodiments according to the present disclosure.

FIG. 11 is a cross-sectional view of a stacked structure in a respective subpixel in some embodiments according to the present disclosure.

FIG. 12 is a cross-sectional view of a respective subpixel in some embodiments according to the present disclosure.

FIG. 13 is a cross-sectional view of a stacked structure in a respective subpixel in some embodiments according to the present disclosure.

FIG. 14A to 14E illustrate a process of fabricating an array substrate in some embodiments according to the present disclosure.

FIG. 15A to 15B illustrate a process of fabricating an array substrate in some embodiments according to the present disclosure.

FIG. 16A to 16E illustrate a process of fabricating an array substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the present disclosure provides an array substrate. In some embodiments, the array substrate includes a plurality of subpixels. In some embodiments, a respective subpixel of the plurality of subpixels includes a first transistor. The first transistor in some embodiments includes a gate electrode; a first electrode on the gate electrode; a semiconductor material layer on a side of the first electrode away from the gate electrode; a second electrode on a side of the semiconductor material layer away from the first electrode; an organic layer on a side of the second electrode away from the semiconductor material layer; and a third electrode on a side of the organic layer away from the second electrode. Optionally, an orthographic projection of the second electrode on a base substrate at least partially overlaps with an orthographic projection of the organic layer on the base substrate.

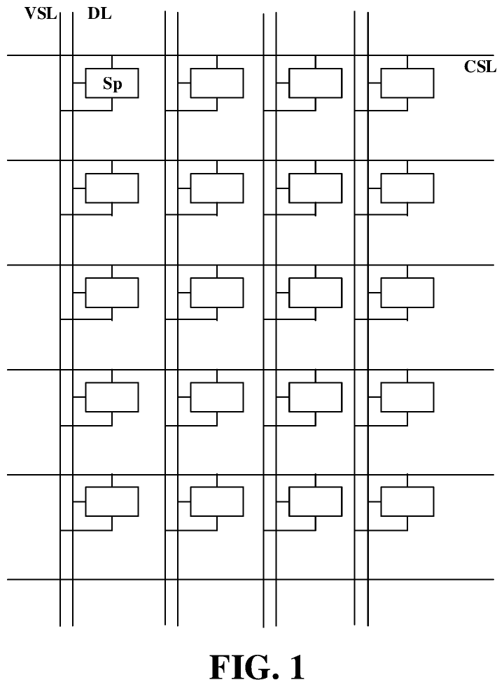

FIG. 1 is a plan view of an array substrate in some embodiments according to the present disclosure. Referring to FIG. 1, the array substrate in some embodiments includes a plurality of subpixels, a plurality of data lines, a plurality of control signal lines, and a plurality of voltage signal lines. A respective subpixel Sp is connected to a voltage signal line VSL, a data line DL, and a control signal line CSL.

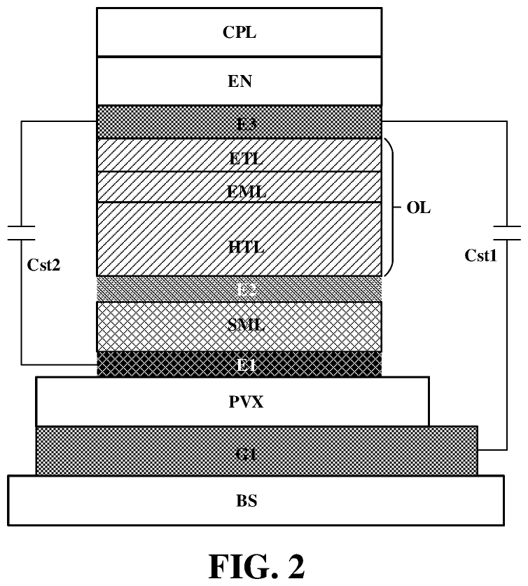

FIG. 2 is a cross-sectional view of a stacked structure in a respective subpixel in some embodiments according to the present disclosure. Referring to FIG. 2, the array substrate in some embodiments includes a first transistor T1. In one example, the first transistor T1 is a vertical organic light emitting transistor that is configured to emit light when driven. In some embodiments, the first transistor T1 has a stacked structure. The stacked structure in some embodiments includes a gate electrode G1; a first electrode E1 on the gate electrode G1; a semiconductor material layer SML on a side of the first electrode E1 away from the gate electrode G1; a second electrode E2 on a side of the semiconductor material layer SML away from the first electrode E1; an organic layer OL on a side of the second electrode away from the semiconductor material layer; and a third electrode E3 on a side of the organic layer OL away from the second electrode E2.

Various appropriate semiconductor materials and various appropriate fabricating methods may be used to make the semiconductor material layer SML. For example, a semiconductor material may be deposited on the substrate by ink-jet printing, spin coating, vapor deposition (e.g., plasma-enhanced chemical vapor deposition), magnetron sputtering, or vacuum deposition. Examples of appropriate semiconductor materials for making the semiconductor material layer SML include inorganic semiconductor materials and organic semiconductor materials. Examples of organic semiconductor materials include organic polymer semiconductor materials and organic small molecule semiconductor materials such as vanadium oxide phthalocyanine. Examples of inorganic semiconductor materials include amorphous silicon, polycrystalline silicon, and metal oxides. Examples of appropriate metal oxide semiconductor materials include, but are not limited to, indium gallium zinc oxide, zinc oxide, gallium oxide, and indium oxide.

In some embodiments, the semiconductor material layer SML functions as at least a part of an active layer of the first transistor T1, the first electrode E1 functions as at least a part of a source electrode of the first transistor T1, and the third electrode E3 functions as at least a part of a drain electrode of the first transistor T1.

FIG. 3 is a circuit diagram of a respective subpixel in some embodiments according to the present disclosure. Referring to FIG. 2 and FIG. 3, in some embodiments, the third electrode E3 is coupled to a voltage signal line VSL, which is configured to provide a voltage signal to the third electrode E3. In one example, the voltage signal provided to the third electrode E3 is a low voltage signal, e.g., a ground voltage signal. In some embodiments, the first electrode E1 is coupled to a data line DL, which is configured to provide a data signal to the first electrode E1. In some embodiments, the gate electrode G1 is coupled to a control signal line, which is configured to provide a control signal to the gate electrode G1. When the gate electrode G1 receives a turning-on signal from the control signal line CSL, the first transistor T1 is turned on, the data signal applies a voltage across the first electrode E1 to the third electrode E3, driving the first transistor T1 to emit light. Data signals of different voltages correspond to different grayscales of image displayed by the respective subpixel.

As discussed above, the first transistor T1 in some embodiments includes an organic layer OL, which includes a light emitting material. In some embodiments, the organic layer OL has a multi-layer structure including a light emitting layer. Optionally, the organic layer includes at least one of an organic light emitting layer; a hole transport layer; a hole injection layer; an electron transport layer; an electron injection layer; a hole barrier layer; or an electron barrier layer. Optionally, the organic layer includes one or more of a hole transport layer, a hole injection layer, a light emitting layer (e.g., a red light emitting layer, a blue light emitting layer, and a green light emitting layer), an electron transport layer, an electron injection layer, a charge generation layer, an electron blocking layer, a hole blocking layer, a prime layer (e.g., a red prime layer, a green prime layer, and a blue prime layer), and a capping layer. When the gate electrode G1 receives a turning-on signal from the control signal line CSL, the first transistor T1 is turned on, the data signal drives the organic layer OL to emit light. In one example depicted in FIG. 2, the organic layer OL includes a hole transport layer HTL, a light emitting layer EML, and an electron transport layer ETL.

Various appropriate conductive materials may be used for making the second electrode E2, the third electrode E3, and the gate electrode G1. For example, a conductive material may be deposited on the substrate by magnetron sputtering, vapor deposition (e.g., plasma-enhanced chemical vapor deposition), or vacuum deposition. Examples of appropriate conductive materials for making the second electrode E2, the third electrode E3, or the gate electrode G1 include substantially transparent conductive materials (for making a substantially transparent second electrode) and reflective conductive materials (for making a reflective second electrode). Examples of appropriate reflective conductive materials include, but are not limited to, silver, copper, aluminum, molybdenum, chromium, neodymium, nickel, manganese, titanium, tantalum, and tungsten. Examples of appropriate substantially transparent conductive materials include substantially transparent metallic conductive materials and substantially transparent non-metallic conductive materials. Examples of substantially transparent non-metallic conductive materials include, but are not limited to, indium tin oxide, indium zinc oxide, indium gallium oxide, and indium gallium zinc oxide. Examples of substantially transparent metallic conductive materials include nano-silver.

According to the materials used for the second electrode E2, the first transistor T1 may be a top-emitting type light emitting transistor, a bottom-emitting type light emitting transistor, or a dual-emitting type light emitting transistor. In one example, the second electrode E2 is a reflective electrode, the third electrode E3 is a substantially transparent electrode, the first transistor T1 is a top-emitting type light emitting transistor, and the array substrate is a top-emitting type array substrate. In another example, the second electrode E2 is a substantially transparent electrode, the third electrode E3 is a reflective electrode, the first transistor T1 is a bottom-emitting type light emitting transistor, and the array substrate is a bottom-emitting type array substrate. In another example, the second electrode E2 is a substantially transparent electrode, the third electrode E3 is a substantially transparent electrode, the first transistor T1 is a dual-emitting type light emitting transistor, and the array substrate is a dual-emitting type array substrate.

Referring to FIG. 2, the second electrode E2 spaces apart the semiconductor material layer SML from the organic layer OL. Optionally, the second electrode E2 is in direct contact with the semiconductor material layer SML on one side, and is in direct contact with the organic layer OL on the other side.

Referring to FIG. 2, the first electrode E1 is between the gate electrode G1 and the semiconductor material layer SML. The first electrode E1 is spaced apart from the gate electrode G1 by one or more insulating layers. Optionally, the first electrode E1 is in direct contact with the semiconductor material layer SML.

Various appropriate conductive materials may be used for making the first electrode E1. For example, a conductive material may be deposited on the substrate by spin coating, ink-jet printing, magnetron sputtering, vapor deposition (e.g., plasma-enhanced chemical vapor deposition), or vacuum deposition. In some embodiments, the first electrode E1 is a perforated electrode, allowing an electric field produced by the gate electrode to modulate the semiconductor material layer SML, which functions as at least a part of an active layer of the first transistor T1. The perforated electrode functions as at least a part of a source electrode of the first transistor T1. As used herein, the term “perforated” refers to that the first electrode E1 does not fully cover an entire surface of an underlying layer (e.g., a passivation layer PVX in FIG. 2). Optionally, at least 1% (e.g., at least 5%, at least 10%, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, at least 98%, or at least 99%) of the underlying layer is not covered (e.g., exposed) by the perforated electrode.

Examples of appropriate conductive materials for making the first electrode E1 include conductive materials having perforated network such as nanotube materials and nanowire materials. Examples of materials having perforated network include carbon nanotube, graphene, metallic or non-metallic mesh electrodes, and metallic or non-metallic nanowires. In one example, the first electrode E1 is made of carbon nanotubes. The material having perforated network in the first electrode E1 may have various appropriate densities (e.g., corresponding to the percentages of exposed surface of the underlying layer discussed above) to allow an electric field produced by the gate electrode to modulate the semiconductor material layer.

In some embodiments, the first electrode E1 is a patterned electrode having a plurality of openings. Examples of appropriate conductive materials for making the first electrode E1 further include silver, copper, aluminum, molybdenum, chromium, neodymium, nickel, manganese, titanium, tantalum, tungsten, indium tin oxide, indium zinc oxide, indium gallium oxide, and indium gallium zinc oxide. In one example, the conductive material is deposited on the substrate, followed by a patterning process using a mask plate to produce a perforated pattern. In one example, the first electrode E1 is a patterned electrode having a plurality of bars spaced apart by a plurality of slits, respectively. In another example, the first electrode E1 is a mesh electrode.

Referring to FIG. 2, the first transistor T1 has a storage capacitor in the stacked structure. The storage capacitance includes at least a first storage capacitance Cst1 formed between the gate electrode G1 and the third electrode E3. Optionally, the storage capacitance further includes a second storage capacitance Cst2 formed between the first electrode E1 and the third electrode E3. In some embodiments, the storage capacitance may further include additional components, e.g., one between the second electrode E2 and the third electrode E3. Because the storage capacitor is inherently included in the stacked structure, a separate storage capacitor is not required. Because of this unique structure, the array substrate has an increase aperture ratio and a lower power consumption.

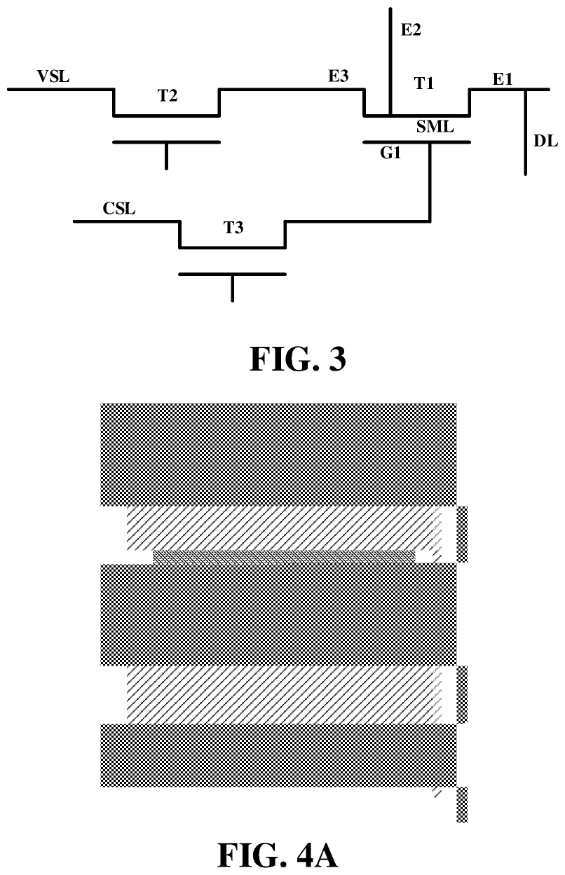

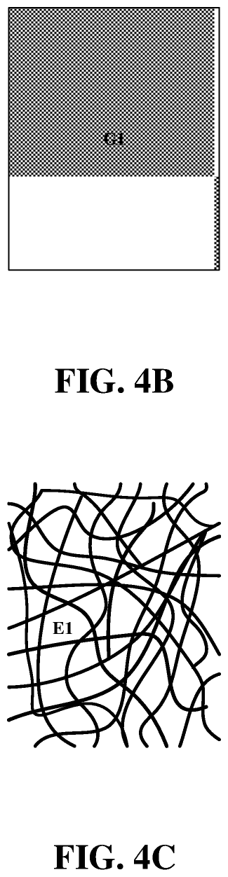

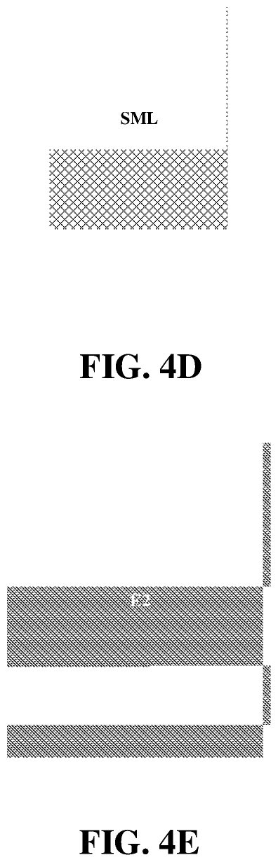

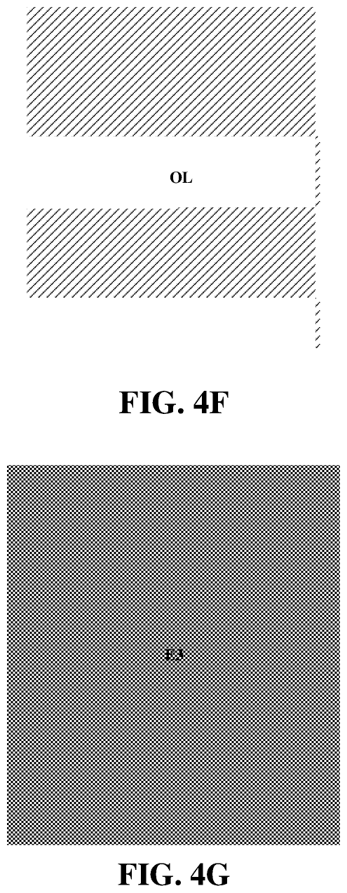

FIG. 4A illustrates the structure in plan view of at least a portion of a stacked structure in a respective subpixel in some embodiments according to the present disclosure. FIG. 4B illustrates the structure of a gate electrode in a respective subpixel of FIG. 4A. FIG. 4C illustrates the structure of a first electrode in a respective subpixel of FIG. 4A. FIG. 4D illustrates the structure of a semiconductor material layer in a respective subpixel of FIG. 4A. FIG. 4E illustrates the structure of a second electrode in a respective subpixel of FIG. 4A. FIG. 4F illustrates the structure of an organic layer in a respective subpixel of FIG. 4A. FIG. 4G illustrates the structure of a third electrode in a respective subpixel of FIG. 4A. Referring to FIG. 4A to FIG. 4G, in some embodiments, an orthographic projection of the second electrode E2 on a base substrate at least partially (e.g., at least 50%, at least 60%, at least 70%, at least 80%, at least 90%, at least 95%) overlaps with an orthographic projection of the organic layer OL on the base substrate. Optionally, the orthographic projection of the organic layer OL on the base substrate covers the orthographic projection of the second electrode E2 on the base substrate.

In some embodiments, the orthographic projection of the second electrode E2 on the base substrate at least partially overlaps with an orthographic projection of the semiconductor material layer SML on the base substrate, and at least partially overlaps with an orthographic projection of the first electrode E1 on the base substrate.

In some embodiments, an orthographic projection of the gate electrode G1 on the base substrate at least partially (e.g., at least 50%, at least 60%, at least 70%, at least 80%, at least 90%, at least 95%) overlaps with an orthographic projection of the semiconductor material layer SML on the base substrate. An increased overlapping between the gate electrode G1 and the semiconductor material layer SML increases an area over which the electric field produced by the gate electrode modulates the semiconductor material layer SML. Optionally, the orthographic projection of the gate electrode G1 on the base substrate covers the orthographic projection of the semiconductor material layer SML on the base substrate.

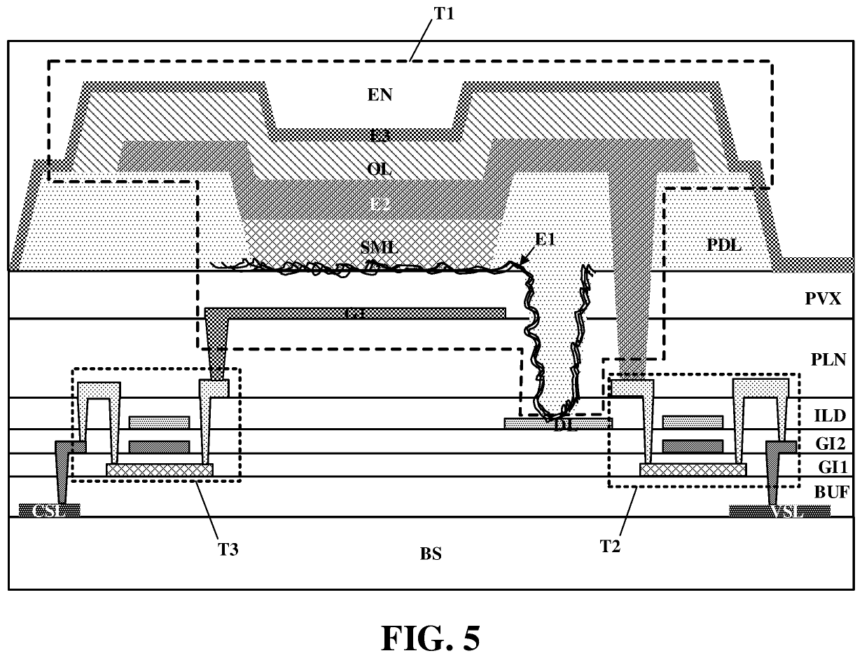

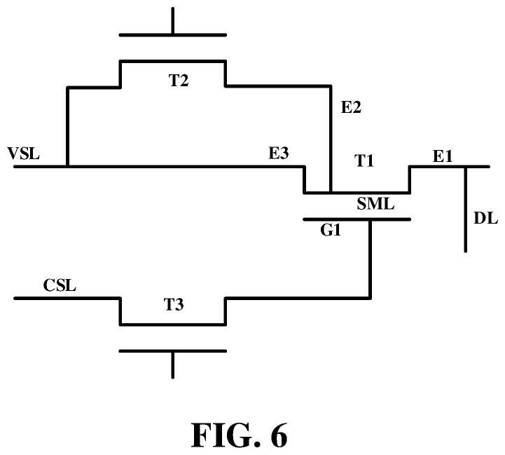

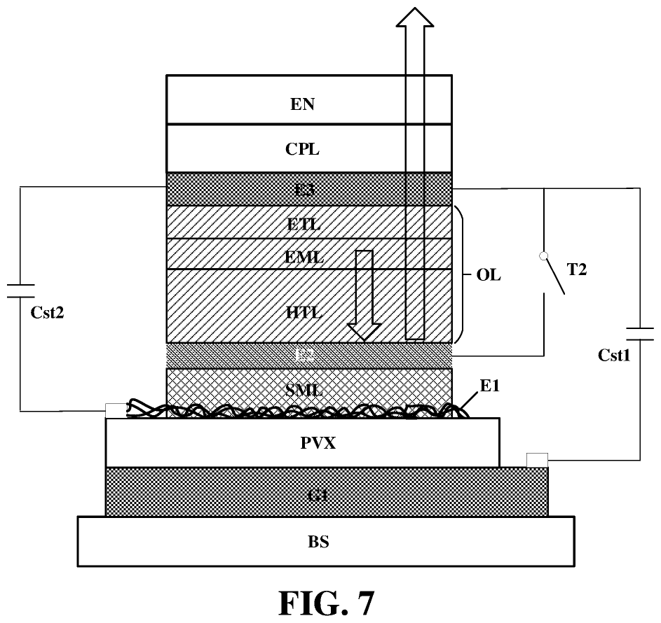

FIG. 5 is a cross-sectional view of a respective subpixel in some embodiments according to the present disclosure. FIG. 6 is a circuit diagram of a respective subpixel in some embodiments according to the present disclosure. FIG. 7 is a cross-sectional view of a stacked structure in a respective subpixel in some embodiments according to the present disclosure. Referring to FIG. 5 to FIG. 7, the second electrode E2 in some embodiments is a reflective electrode. As shown in FIG. 7, light emitted from the light emitting layer EML is reflected by the second electrode E2, and light reflected by the second electrode E2 emits out of the first transistor from a top side. The third electrode E3 is a substantially transparent electrode. The stacked structure in some embodiments further include a capping layer CPL configured to extract light reflected by the second electrode E2. In one example, the capping layer CPL is made of a low refractive index material such as LiF. In another example, the capping layer CPL is made of a high refractive index material such as silicon nitride. The stacked structure in some embodiments further include an encapsulating layer EN encapsulating the first transistor.

In the array substrate depicted in FIG. 5 to FIG. 7, the second electrode E2 is between the semiconductor material layer SML and the organic layer OL. By having a reflective second electrode, the semiconductor material layer SML and the passivation layer PVX are excluded from being parts of a microcavity in the first transistor T1, enhancing light emitting efficiency of the light emitting transistor.

Referring to FIG. 5 to FIG. 7, the respective subpixel in some embodiments further includes a second transistor T2 coupled to the second electrode E2. The second transistor T2 is configured to connect or disconnect the second electrode E2 with a voltage signal line VSL. In some embodiments, the voltage signal line VSL is a signal line configured to provide a signal (e.g., a low voltage signal) to the third electrode E3.

In related array substrate, when first transistor T1 is turned off to switch the respective subpixel to a dark state, residual carriers in the semiconductor material layer SML may still drive the light emitting layer EML to emit small amount of light. In some embodiments, when the first transistor T1 is turned off, the second electrode E2 is configured to receive the signal (e.g., a low voltage signal) from the voltage signal line VSL. When the second electrode E2 is connected to the voltage signal line VSL, the light emitting layer EML is prevented from emitting light, maintaining the dark state of the respective subpixel. The second electrode E2 is in direct contact with the semiconductor material layer SML. Residual carriers in the semiconductor material layer SML may be eliminated by having the second electrode E2 receiving a low voltage signal.

Optionally, the second transistor T2 is configured to electrically connect the second electrode E2 with the voltage signal line VSL when the gate electrode G1 is configured to receive a turning-off signal. The second electrode E2 connects the semiconductor material layer SML with the voltage signal line VSL, thereby maintaining the respective subpixel in dark state.

Optionally, the second transistor T2 is configured to electrically disconnect the second electrode E2 with the voltage signal line VSL when the gate electrode G1 is configured to receive a turning-on signal. When the second electrode E2 is disconnected with the voltage signal line VSL, the second electrode E2, together with the first electrode E1, may be considered as parts of the source electrode of the first transistor T1.

Referring to FIG. 5, the array substrate in some embodiments includes a base substrate BS; a control signal line CSL and a voltage signal line VSL on the base substrate BS; a buffer layer BUF on a side of the control signal line CSL and the voltage signal line VSL away from the base substrate BS; active layers of a second transistor T2 and a third transistor T3 on a side of the buffer layer BUF away from the base substrate BS; a first gate insulating layer GI1 on a side of the active layers of the second transistor T2 and the third transistor T3 away from the buffer layer BUF; first gate electrodes of the second transistor T2 and the third transistor T3 on a side of the first gate insulating layer GI1 away from the buffer layer BUF; a second gate insulating layer GI2 on a side of the first gate electrodes of the second transistor T2 and the third transistor T3 away from the first gate insulating layer GI1; a data line DL, and second gate electrodes of the second transistor T2 and the third transistor T3 on a side of the second gate insulating layer GI2 away from the first gate insulating layer GI1 ; an inter-layer dielectric layer ILD on a side of the data line DL, and the second gate electrodes of the second transistor T2 and the third transistor T3, away from the second gate insulating layer GI2; source electrodes and drain electrodes of the second transistor T2 and the third transistor T3 on a side of the inter-layer dielectric layer ILD away from the second gate insulating layer GI2; a planarization layer PLN on a side of the source electrodes and drain electrodes of the second transistor T2 and the third transistor T3 away from the inter-layer dielectric layer ILD; a gate electrode G1 of the first transistor T1 on a side of the planarization layer PLN away from the inter-layer dielectric layer ILD; a passivation layer PVX on a side of the gate electrode G1 away from the planarization layer PLN; a first electrode E1 on a side of the passivation layer PVX away from the planarization layer PLN, the first electrode E1 connected to the data line through a via extending through the passivation layer PVX, the planarization layer PLN, and the inter-layer dielectric layer ILD; a pixel definition layer PDL on a side of the passivation layer PVX away from the planarization layer PLN, the pixel definition layer PDL defining a plurality of first apertures; a semiconductor material layer SML on a side of the first electrode E1 away from the passivation layer PVX, the semiconductor material layer SML received in the plurality of first apertures defined by the pixel definition layer PDL; a second electrode E2 on a side of the semiconductor material layer SML away from the first electrode E1, the second electrode E2 connected to the second transistor T2 through a via extending through the pixel definition layer PDL, the passivation layer PVX, and the planarization layer PLN; an organic layer OL on a side of the second electrode E2 away from the semiconductor material layer SML; a third electrode E3 on a side of the organic layer OL away from the second electrode E2; and an encapsulating layer EN on a side of the third electrode E3 away from the organic layer OL.

In the example depicted in FIG. 5 and FIG. 7, the first electrode E1 is made of carbon nanotubes.

In one example, the second electrode E2 has a thickness in a range of 30 nm to 200 nm.

In one example, the semiconductor material layer SML has a thickness in a range of 300 nm to 1000 nm.

In one example, the passivation layer PVX has a thickness in a range of 20 nm to 2000 nm.

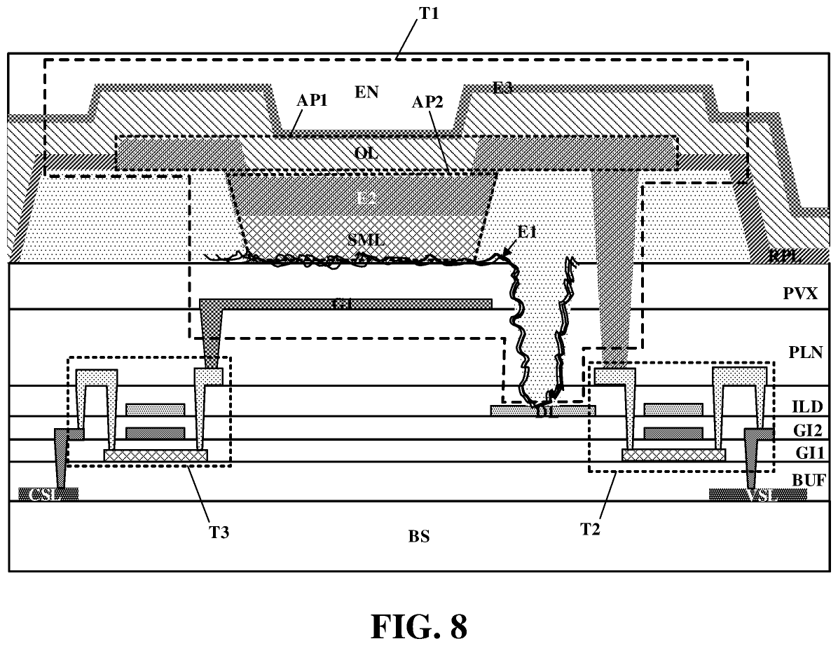

FIG. 8 is a cross-sectional view of a respective subpixel in some embodiments according to the present disclosure. Referring to FIG. 8, the array substrate in some embodiments further includes a repellent protective layer RPL. Optionally, the repellent protective layer RPL is on a side of the pixel definition layer PDL away from the base substrate BS.

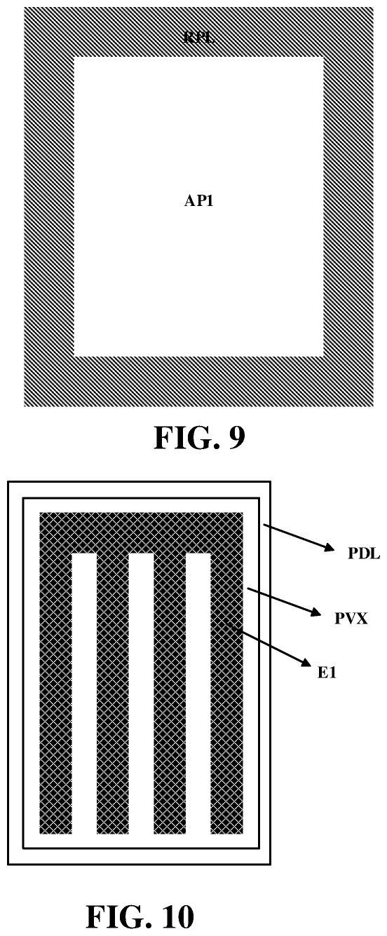

The repellent protective layer RPL defines a plurality of first apertures AP1. FIG. 9 illustrates the structure of a respective first aperture in some embodiments according to the present disclosure. Referring to FIG. 8 and FIG. 9, a respective first aperture of the plurality of first apertures AP1 is configured to receive the second electrode E2 of the respective subpixel.

The repellent protective layer RPL provides a clear boundary for the second electrode E2, particularly when the second electrode E2 is made of a metal such as silver. The repellent protective material in the repellent protective layer RPL prevents the electrode material from depositing on its surface. A surface of the repellent protective layer RPL has a desorption activation energy that is greater than or equal to a diffusion activation energy of the surface, with respect to the electrode material (metals such as magnesium and silver) of the second electrode E2. Optionally, the desorption activation energy is less than or equal to about 2.5 times of the diffusion activation energy of the surface, with respect to the electrode material of the second electrode E2.

The pixel definition layer PDL defines a plurality of second apertures AP2. A respective second aperture of the plurality of second apertures AP2 is configured to receive the semiconductor material layer SML of the respective subpixel. Optionally, the respective second aperture is further configured to receive at least a part of the second electrode E2 of the respective subpixel.

Various appropriate repellent protective materials and various appropriate fabricating methods may be used to make the repellent protective layer RPL. For example, a repellent protective material may be deposited on the substrate by ink-jet printing, spin coating, vapor deposition (e.g., plasma-enhanced chemical vapor deposition), magnetron sputtering, or vacuum deposition. Examples of appropriate repellent protective materials include organic topological insulating materials. Topological insulating materials refer to materials with an insulating bulk and a conducting edge or a conducting surface. Examples of organic topological insulating materials include 2-(4-tert-butylphenyl)-5-(4-biphenylyl)-1,3,4-oxadiazole, 2-(4-biphenylyl)-5-phenyl-1,3,4-oxadiazole, 1,3-bis(N-carbazolyl)benzene, 3-(Biphenyl-4-yl)-5-(4-tert-butylphenyl)-4-phenyl-4H-1,2,4-triazole, N,N′-Bis-(1-naphthalenyl)-N,N′-bis-phenyl-(1,1′-biphenyl)-4,4′-diamine, 4-(1-Naphthyl)-3,5-diphenyl-1,2,4-triazole, 3,5-bis(4-tert-butylphenyl)-4-phenyl-1,2,4-triazole, 2,5-Di(naphthalen-1-yl)-1,3,4-oxadiazole, 2-(tert-Butyl)-9,10-di(2-naphthalenyl)anthracene, 4,4′-bis(N-carbazolyl)-1,1′-biphenyl, Bis(8-hydroxy-2-methylquinoline)-(4-phenylphenoxy)aluminum, 9-([1,1′-biphenyl]-3-yl)-3-broMo-9H-carbazole, and Tris[2-phenylpyridinato-C2,N]iridium(III).

In one example, the repellent protective layer RPL has a thickness greater than 15 nm. The thickness of the repellent protective layer RPL is less than the thickness of the second electrode E2. In another example, the thickness of the repellent protective layer RPL is 10% to 80% (e.g., 10% to 20%, 20% to 30%, 30% to 40%, 40% to 50%, 50% to 60%, 60% to 70%, or 70% to 80%) of the thickness of the second electrode E2.

Referring to FIG. 5 to FIG. 8, the respective subpixel in some embodiments further includes a third transistor T3 configured to connect or disconnect the gate electrode G1 with a control signal line CSL. When the third transistor is turned on, the third transistor T3 is configured to allow a control signal from the control signal line CSL to pass to the gate electrode G1, thereby driving the first transistor T1 to emit light.

As discussed above, the first electrode E1 is a patterned electrode having a plurality of openings. FIG. 10 illustrates the structure of a perforated electrode in some embodiments according to the present disclosure. Referring to FIG. 10, the first electrode E1 in some embodiments is a patterned electrode having a plurality of bars spaced apart by a plurality of slits, respectively. The plurality of slits allow an electric field produced by the gate electrode to modulate the semiconductor material layer.

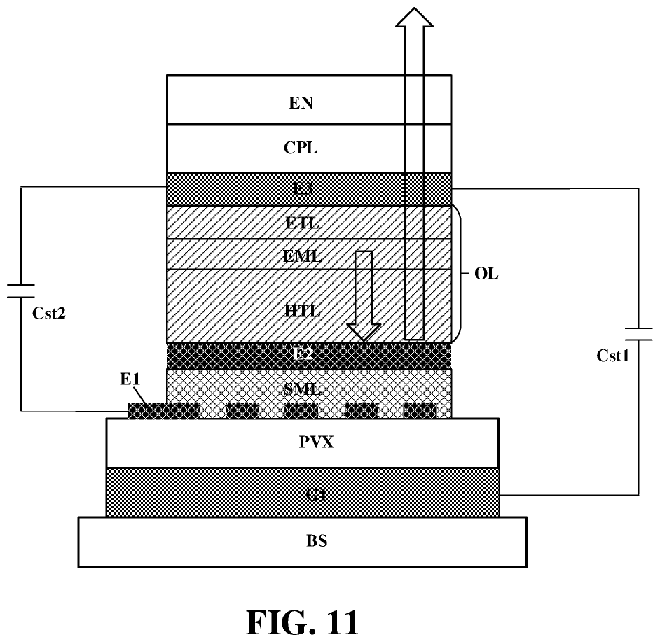

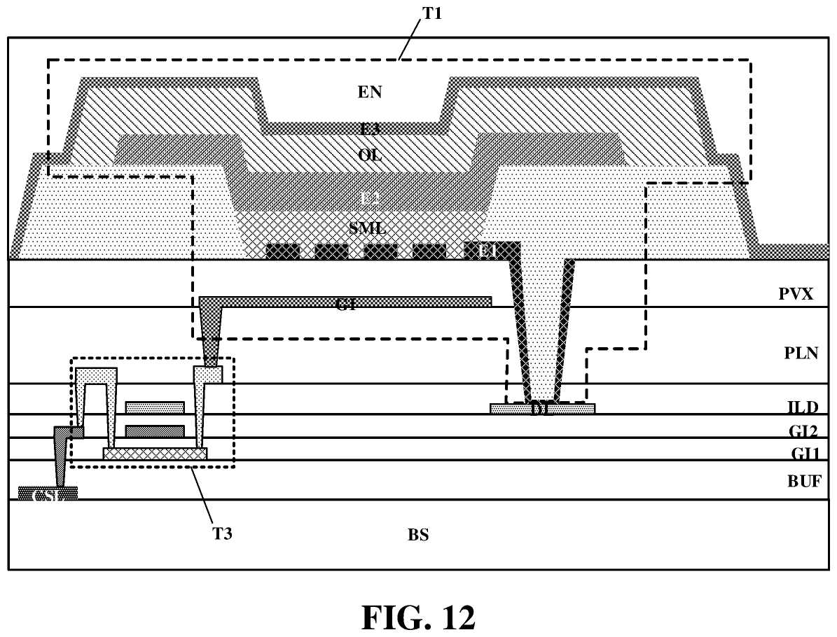

FIG. 11 is a cross-sectional view of a stacked structure in a respective subpixel in some embodiments according to the present disclosure. FIG. 12 is a cross-sectional view of a respective subpixel in some embodiments according to the present disclosure. FIG. 11 and FIG. 12 illustrate a respective subpixel having a first electrode E1 that is a patterned electrode.

Referring to FIG. 12, in some embodiments, the array substrate lacks a second transistor. In some embodiments, the second electrode E2 is electrically connected to the semiconductor material layer SML and the organic layer OL, but is otherwise electrically isolated. For example, the second electrode E2 is otherwise only in contact with the pixel definition layer PDL, which is made of an insulating material. In this example, the second electrode E2 functions as a part of the source electrode of the first transistor T1. For example, the second electrode E2, together with the first electrode E1, may be considered as parts of the source electrode of the first transistor T1.

Referring to FIG. 11 and FIG. 12, the second electrode E2 in some embodiments is a reflective electrode. As shown in FIG. 11, light emitted from the light emitting layer EML is reflected by the second electrode E2, and light reflected by the second electrode E2 emits out of the first transistor from a top side. The third electrode E3 is a substantially transparent electrode.

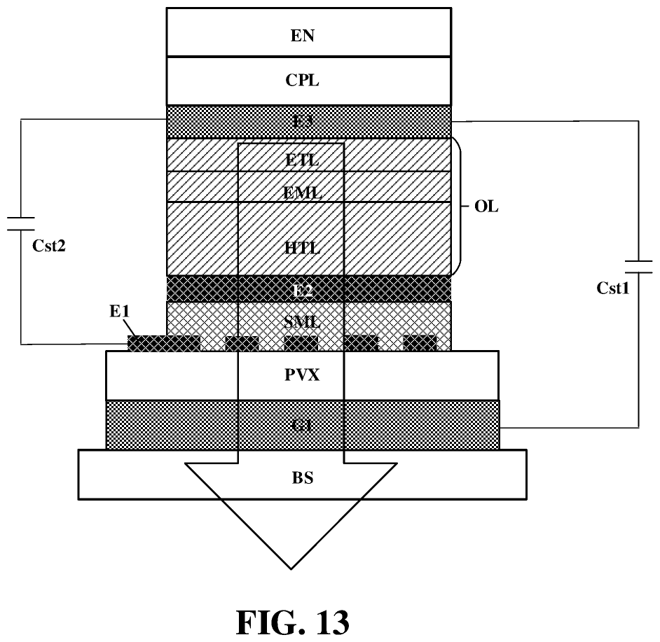

FIG. 13 is a cross-sectional view of a stacked structure in a respective subpixel in some embodiments according to the present disclosure. Referring to FIG. 13, in some embodiments, the second electrode E2 is a substantially transparent electrode. In some embodiments, the third electrode E3 is a reflective electrode, the first electrode E1 is a substantially transparent electrode, and the gate electrode G1 is a substantially transparent electrode. Light emitted from the light emitting layer EML is reflected by the third electrode E3, light reflected by the third electrode E3 substantially transmits through the second electrode E2, the first electrode E1, and the gate electrode G1, and emits out of the first transistor from a bottom side. The array substrate is a bottom-emitting type array substrate.

In another aspect, the present disclosure provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc.

In another aspect, the present disclosure provides a method of fabricating an array substrate. In some embodiments, the method includes forming a plurality of subpixels. In some embodiments, forming a respective subpixel of the plurality of subpixels includes forming a first transistor. In some embodiments, forming the first transistor includes forming a gate electrode; forming a first electrode on the gate electrode; forming a semiconductor material layer on a side of the first electrode away from the gate electrode; forming a second electrode on a side of the semiconductor material layer away from the first electrode; forming an organic layer on a side of the second electrode away from the semiconductor material layer; and forming a third electrode on a side of the organic layer away from the second electrode. Optionally, an orthographic projection of the second electrode on a base substrate at least partially overlaps with an orthographic projection of the organic layer on the base substrate. Optionally, the orthographic projection of the second electrode on the base substrate at least partially overlaps with an orthographic projection of the semiconductor material layer on the base substrate, and at least partially overlaps with an orthographic projection of the first electrode on the base substrate. Optionally, an orthographic projection of the gate electrode on the base substrate at least partially overlaps with an orthographic projection of the semiconductor material layer on the base substrate.

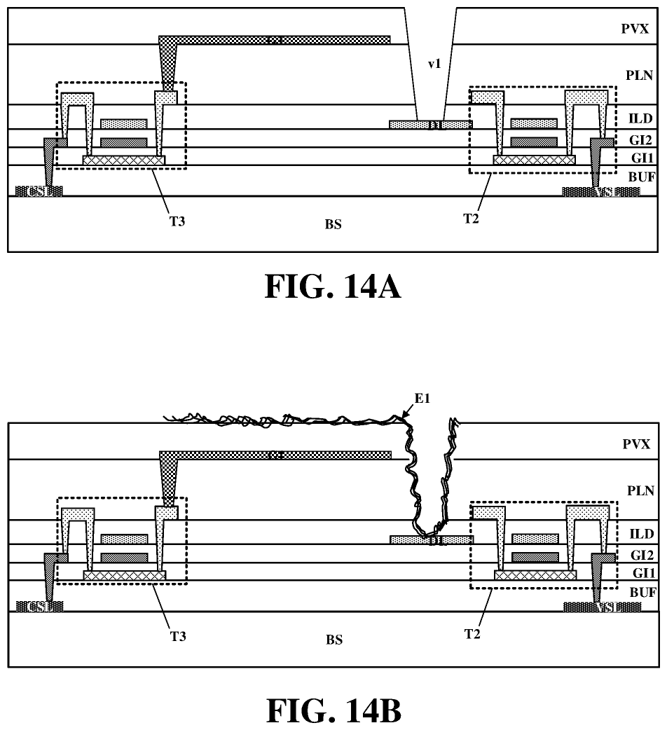

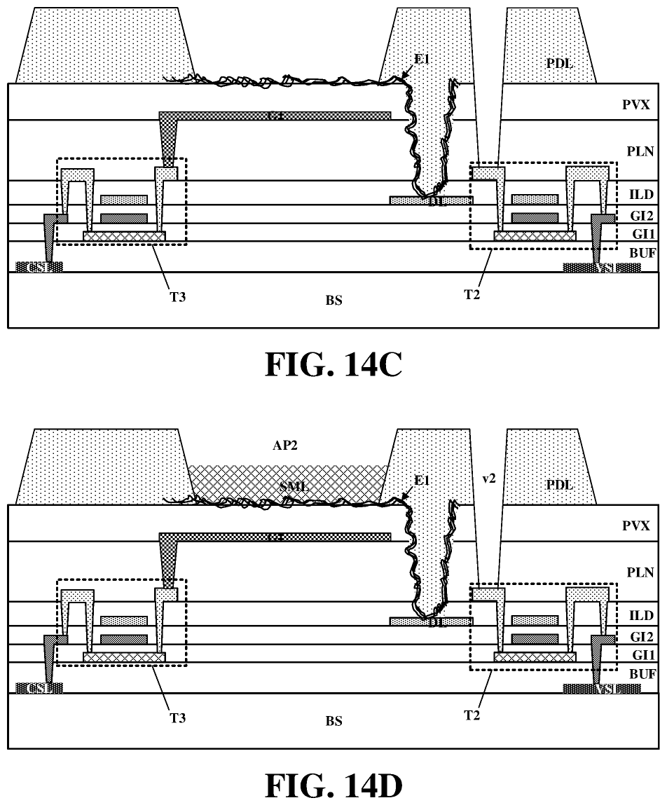

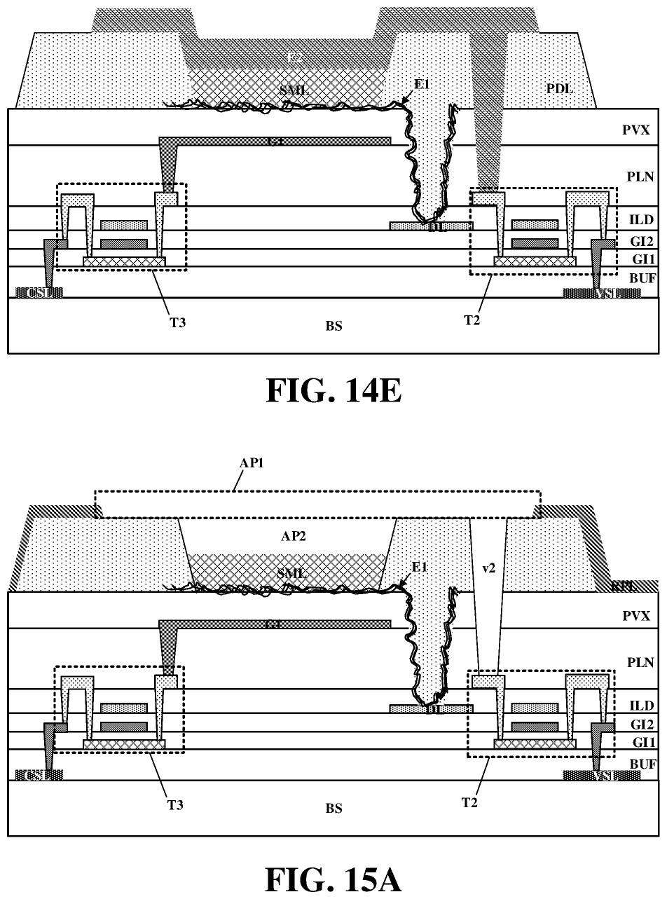

FIG. 14A to 14E illustrate a process of fabricating an array substrate in some embodiments according to the present disclosure. Referring to FIG. 14A, a backplate comprising the second transistor T2, the third transistor T3, the data line DL, the control signal line CSL, the voltage signal line VSL, and the gate electrode G1 is formed. A first via v1 is formed to extend through the passivation layer PVX, the planarization layer PLN, and the inter-layer dielectric layer ILD, exposing a surface of the data line DL.

Referring to FIG. 14B, the first electrode E1 is formed on a side of the passivation layer PVX away from the planarization layer PLN. In one example, the first electrode E1 is formed by ink-jet printing or spin coating an electrode material such as carbon nanotubes. The first electrode E1 extends through the first via to connect to the data line DL.

Referring to FIG. 14C, a pixel definition layer PDL is formed on a side of the first electrode E1 and the passivation layer PVX away from the planarization layer PLN. The pixel definition layer PDL is formed to define a plurality of second apertures AP2. Subsequently, a second via v2 is formed to extend through the pixel definition layer PDL and the passivation layer PVX, the planarization layer PLN, exposing a surface of a drain electrode of the second transistor T2.

Referring to FIG. 14D, the semiconductor material layer SML is formed in the plurality of second apertures AP2. The semiconductor material layer SML may be formed by ink-jet printing or vapor deposition.

Referring to FIG. 14E, the second electrode E2 is formed on a side of the semiconductor material layer SML and the pixel definition layer PDL. A portion of the second electrode E2 is received in a respective second aperture of the plurality of second apertures AP2. The second electrode E2 extends through the second via v2 to connect to the drain electrode of the second transistor T2.

Referring to FIG. 5, the organic layer OL is formed on a side of the second electrode E2 away from the semiconductor material layer SML; the third electrode E3 is formed on a side of the organic layer OL away from the second electrode E2; and the encapsulating layer EN is formed on a side of the third electrode E3 away from the organic layer OL.

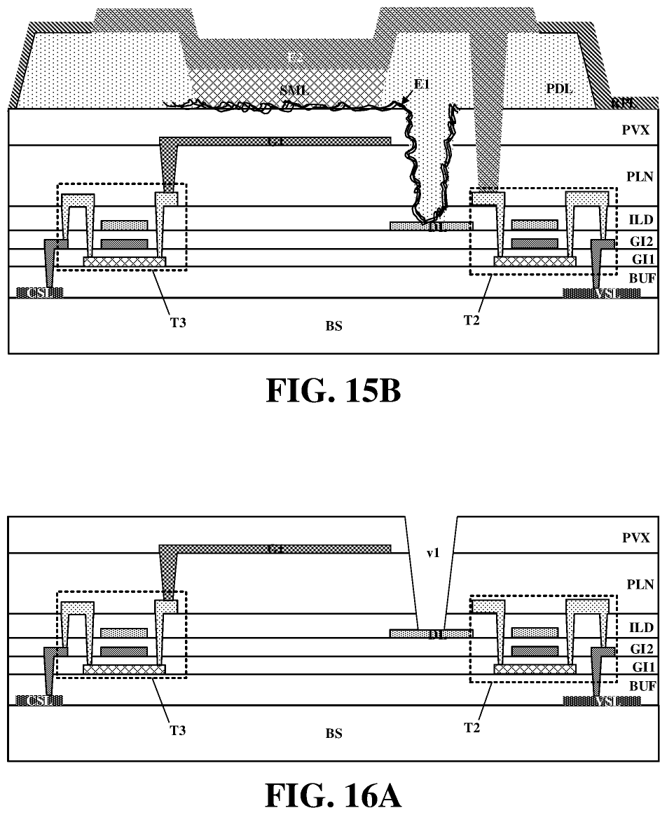

FIG. 15A to 15B illustrate a process of fabricating an array substrate in some embodiments according to the present disclosure. Referring to FIG. 15A, the semiconductor material layer SML is formed in the plurality of second apertures AP2 (as depicted in FIG. 14A to FIG. 14D). The repellent protective layer RPL is formed on a side of the pixel definition layer PDL away from the base substrate BS, e.g., by fine metal mask vapor deposition. The repellent protective layer RPL is formed to define a plurality of first apertures AP1.

Referring to FIG. 15B, the second electrode E2 is formed on a side of the semiconductor material layer SML and the pixel definition layer PDL, e.g., by vapor deposition. A portion of the second electrode E2 is received in a respective second aperture of the plurality of second apertures AP2. The second electrode E2 extends through the second via v2 to connect to the drain electrode of the second transistor T2.

Referring to FIG. 8, the organic layer OL is formed on a side of the second electrode E2 away from the semiconductor material layer SML; the third electrode E3 is formed on a side of the organic layer OL away from the second electrode E2; and the encapsulating layer EN is formed on a side of the third electrode E3 away from the organic layer OL.

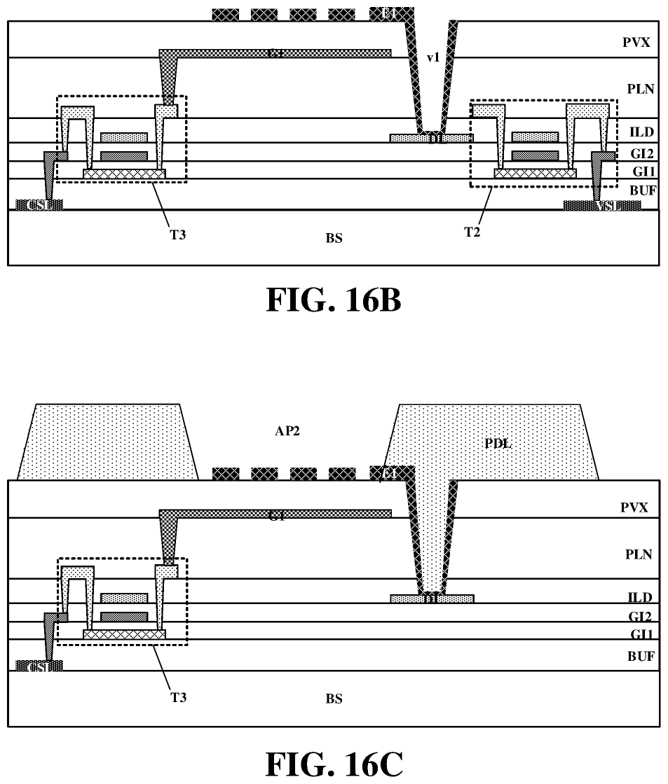

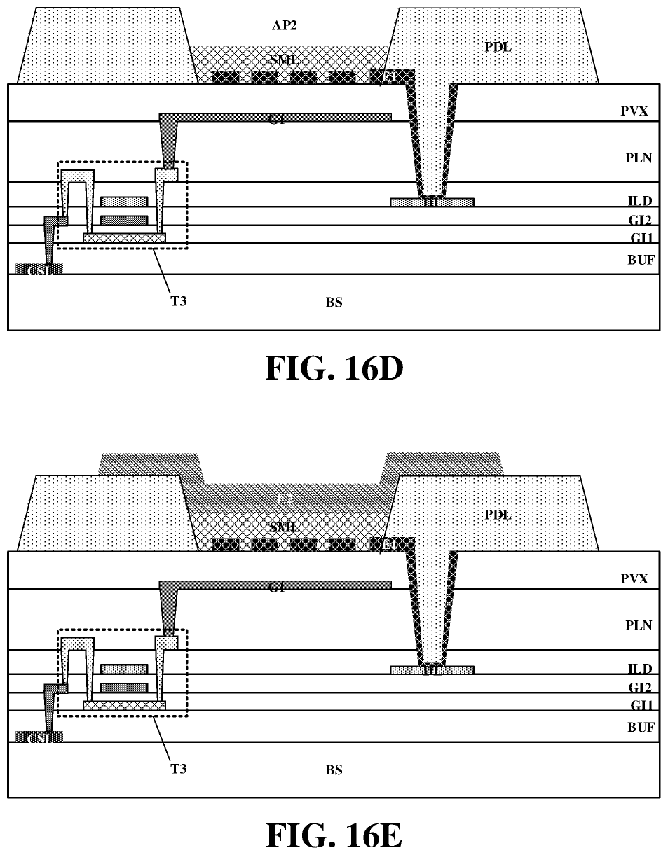

FIG. 16A to 16E illustrate a process of fabricating an array substrate in some embodiments according to the present disclosure. Referring to FIG. 16A, a backplate comprising the second transistor T2, the third transistor T3, the data line DL, the control signal line CSL, the voltage signal line VSL, and the gate electrode G1 is formed. A first via v1 is formed to extend through the passivation layer PVX, the planarization layer PLN, and the inter-layer dielectric layer ILD, exposing a surface of the data line DL.

Referring to FIG. 16B, the first electrode E1 is formed on a side of the passivation layer PVX away from the planarization layer PLN. In one example, the first electrode E1 is formed by depositing an electrode material on the passivation layer PVX, followed by patterning the electrode material to form a patterned electrode. The first electrode E1 extends through the first via to connect to the data line DL.

Referring to FIG. 16C, a pixel definition layer PDL is formed on a side of the first electrode E1 and the passivation layer PVX away from the planarization layer PLN. The pixel definition layer PDL is formed to define a plurality of second apertures AP2.

Referring to FIG. 16D, the semiconductor material layer SML is formed in the plurality of second apertures AP2. The semiconductor material layer SML may be formed by ink-jet printing or vapor deposition.

Referring to FIG. 16E, the second electrode E2 is formed on a side of the semiconductor material layer SML and the pixel definition layer PDL. A portion of the second electrode E2 is received in a respective second aperture of the plurality of second apertures AP2.

Referring to FIG. 12, the organic layer OL is formed on a side of the second electrode E2 away from the semiconductor material layer SML; the third electrode E3 is formed on a side of the organic layer OL away from the second electrode E2; and the encapsulating layer EN is formed on a side of the third electrode E3 away from the organic layer OL.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising a plurality of subpixels, wherein a respective subpixel of the plurality of subpixels comprises a first transistor;
wherein the first transistor comprises:
a gate electrode;
a first electrode on the gate electrode;
a semiconductor material layer on a side of the first electrode away from the gate electrode;
a second electrode on a side of the semiconductor material layer away from the first electrode;
an organic layer on a side of the second electrode away from the semiconductor material layer; and
a third electrode on a side of the organic layer away from the second electrode;
wherein an orthographic projection of the second electrode on a base substrate at least partially overlaps with an orthographic projection of the organic layer on the base substrate.

2. The array substrate of claim 1, wherein the orthographic projection of the second electrode on the base substrate at least partially overlaps with an orthographic projection of the semiconductor material layer on the base substrate, and at least partially overlaps with an orthographic projection of the first electrode on the base substrate.

3. The array substrate of claim 1, wherein an orthographic projection of the gate electrode on the base substrate at least partially overlaps with an orthographic projection of the semiconductor material layer on the base substrate.

4. The array substrate of claim 1, wherein the second electrode is a reflective electrode.

5. The array substrate of claim 1, further comprising a capping layer on a side of the third electrode away from the second electrode, and configured to extract light reflected by the second electrode.

6. The array substrate of claim 1, further comprising an encapsulating layer on a side of the third electrode away from the second electrode, encapsulating the first transistor.

7. The array substrate of claim 1, wherein the first transistor is a top-emitting type light emitting transistor;
the array substrate is a top-emitting type array substrate; and
light emitted from the organic layer is configured to emit out of the first transistor along a direction from the second electrode to the third electrode.

8. The array substrate of claim 1, wherein the first transistor is a bottom-emitting type light emitting transistor;
the array substrate is a bottom-emitting type array substrate; and
light emitted from the organic layer is configured to emit out of the first transistor along a direction from the third electrode to the second electrode.

9. The array substrate of claim 1, wherein the respective subpixel further comprises a second transistor coupled to the second electrode;
the second transistor is configured to connect or disconnect the second electrode with a voltage signal line; and
the voltage signal line is a signal line configured to provide a signal to the third electrode.

10. The array substrate of claim 1, wherein the second electrode is electrically connected to the semiconductor material layer and the organic layer, and is otherwise electrically isolated.

11. The array substrate of claim 1, wherein the second electrode is a substantially transparent electrode.

12. The array substrate of claim 1, wherein the first electrode is a perforated electrode, configured to allow an electric field produced by the gate electrode to modulate the semiconductor material layer, which functions as at least a part of an active layer of the first transistor.

13. The array substrate of claim 12, wherein the first electrode comprises a carbon nanotube material.

14. The array substrate of claim 12, wherein the first electrode comprises a patterned electrode having a plurality of openings.

15. The array substrate of claim 1, further comprising a repellent protective layer defining a plurality of first apertures, a respective first aperture of the plurality of first apertures receiving the second electrode of the respective subpixel.

16. The array substrate of claim 15, wherein a thickness of the repellent protective layer is 10% to 80% of a thickness of the second electrode.

17. The array substrate of claim 16, wherein the repellent protective layer comprises an organic topological insulating material.

18. The array substrate of claim 1, further comprising a pixel definition layer defining a plurality of second apertures, a respective second aperture of the plurality of second apertures receiving the semiconductor material layer of the respective subpixel, and receiving at least a part of the second electrode of the respective subpixel.

19. The array substrate of claim 1, wherein the respective subpixel further comprises a third transistor configured to connect or disconnect the gate electrode with a control signal line.

20. A display apparatus, comprising the array substrate of claim 1.
